(19) United States
(12) Patent Application Publication
(10) Pub. No.: US 2011/0065239 A1
(43) Pub. Date: Mar. 17, 2011

(54) METHOD OF FABRICATING A SEMICONDUCTOR DEVICE AND SEMICONDUCTOR PRODUCTION EQUIPMENT

(75) Inventor: Eiichi Hosomi, Kanagawa-ken (JP)

(73) Assignee: KABUSHIKI KAISHA TOSHIBA, Tokyo (JP)

(21) Appl. No.: 12/874,547

(22) Filed: Sep. 2, 2010

(30) Foreign Application Priority Data
Sep. 11, 2009 (JP) 2009-210551

(51) Int. Cl. H01L 21/50; B29C 65/00; B29C 65/02; B29C 65/08

(52) U.S. Cl. 438/107; 156/580; 156/583.1; 156/580.1; 257/E21.499

(57) ABSTRACT

A present embodiment provides a method of fabricating a semiconductor device includes tentatively compressing a second electrode formed on a second semiconductor chip in a substrate to a first electrode on a first semiconductor chip, at least one of the first electrode and the second electrode being constituted with a metal protrusion, and fixedly compressing between the first electrode and the second electrode.

### CROSS REFERENCE TO RELATED APPLICATION

This application is based upon and claims the benefit of priority from prior Japanese Patent Application NO. 2009-210551, filed on Sep. 11, 2009, the entire contents of which are incorporated herein by reference.

### FIELD

Exemplary embodiments described herein relate to a method of fabricating a semiconductor device and semiconductor production equipment.

### BACKGROUND

Recently, electronics has been highly sophisticated and miniaturized. A plurality of semiconductor chips are disposed in a semiconductor package, each semiconductor chip in the semiconductor package are connected each other and encapsulated as a system in package structure, which is called as a SiP structure hereinafter. Accordingly, technology with decreasing a mounting area has been used.

Chip on chip, which is called CoC hereinafter, is known as a kind of the SiP structures. A semiconductor chip is stacked on another semiconductor chip in a CoC structure.

In the CoC structure, a surface of a lower semiconductor chip is faced to a surface of an upper semiconductor chip to connect between the chips as flip-chip by using fine bump electrodes, so that the two semiconductor chip is electrically wired.

As forming a CoC structure, each of the two semiconductor chips is individualized by dicing, each semiconductor chip is connected each other by the bump electrode.

On the other hand, the upper semiconductor chip is individualized by dicing and the lower semiconductor chip is retained as a state formed on the semiconductor wafer, so that each semiconductor chip is connected each other by the bump electrode as another approach.

In these two methods, the later case can be simply aligned between bump positions, be performed with a die sort test after the CoC connection. Further, back surface lapping and dicing can be performed in a wafer state on the later case as compared to the former case. Namely, the later case has an advantage to the former case.

### BRIEF DESCRIPTION OF THE DRAWINGS

FIG. 1 is a plane view showing a semiconductor wafer according to a first embodiment;

FIG. 2 is a cross-sectional view showing a portion of semiconductor production equipment according to the first embodiment;

FIG. 3 is a cross-sectional view showing a portion of the semiconductor production equipment according to the first embodiment;

FIG. 4 is a plane view showing the semiconductor wafer according to the first embodiment;

FIG. 5 is a cross-sectional view showing a portion of the semiconductor production equipment according to the first embodiment;

FIG. 6 is a plane view showing the semiconductor wafer according to the first embodiment;

FIG. 7 is a plane view showing the semiconductor wafer according to the first embodiment;

FIG. 8 is a plane view showing the semiconductor wafer according to the first embodiment;

FIG. 9 is a plane view showing the semiconductor wafer according to the first embodiment;

FIG. 10 is a plane view showing the semiconductor wafer according to the first embodiment;

FIG. 11 is a plane view showing the semiconductor wafer according to the first embodiment;

FIG. 12 is a plane view showing the semiconductor wafer according to the first embodiment;

FIG. 13 is a plane view showing the semiconductor wafer according to the first embodiment;

FIG. 14 is a cross-sectional view showing a portion of a semiconductor production equipment according to a second embodiment;

FIG. 15 is a cross-sectional view showing a portion of the semiconductor production equipment according to the second embodiment;

FIG. 16 is a cross-sectional view showing a portion of the semiconductor production equipment according to the second embodiment;

FIG. 17 is a cross-sectional view showing a portion of a circuit substrate production equipment according to a third embodiment;

FIG. 18 is a cross-sectional view showing a portion of the circuit substrate production equipment according to the third embodiment;

FIG. 19 is a cross-sectional view showing a portion of the circuit substrate production equipment according to the third embodiment.

### DETAILED DESCRIPTION

A present embodiment provides a method of fabricating a semiconductor device has a tentative compression process and a fixed compression process, subsequently.

In the tentative compression process, a second electrode of a second semiconductor chip is tentatively compressed on a first electrode of a first semiconductor chip. On the other hand, the second electrode of the second semiconductor chip is fixedly compressed on the first electrode of the first semiconductor chip in the fixed compression process. In the method, at least one of the first electrode and the second electrode is constituted with a metal protrusion.

Embodiments of the present disclosure will be described below in detail with reference to the attached drawings. It should be noted that the present disclosure is not restricted to the embodiments but covers their equivalents. Throughout the attached drawings, similar or same reference numerals show similar, equivalent or same components.

### First Embodiment

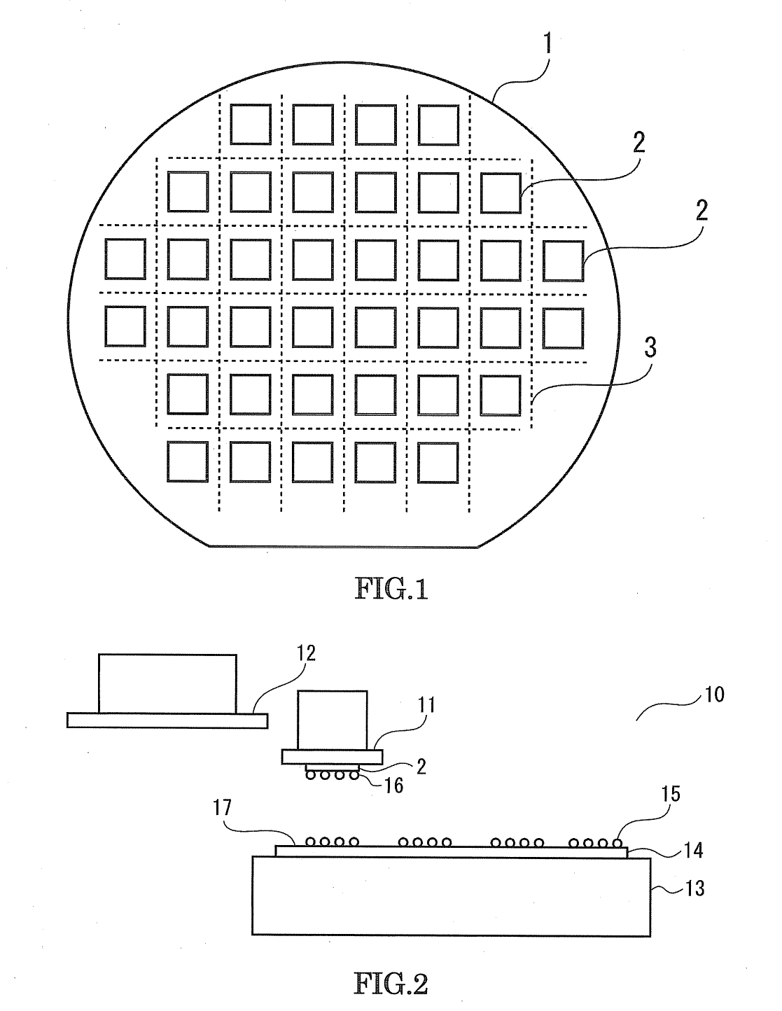

A method of fabricating a semiconductor device according to a first embodiment are shown in FIGS. 1-6. FIGS. 1, 4 and 6 are plane views showing a semiconductor wafer, and FIGS. 2, 3 and 5 are cross-sectional views showing a portion of a semiconductor production equipment.

As shown in FIG. 1, a plurality of semiconductor chips 2, each having a semiconductor element, a wiring, a bump electrode or the like, which are not illustrated, are formed in a semiconductor wafer 1. The semiconductor chips 2 are divided by dicing lines. The semiconductor wafer 1 shown in FIG. 1 has an orientation flat. On the other hand, a semiconductor wafer having a notch is also suitable. In other words, a shape and a size of the semiconductor wafer are not restricted.

Next, the semiconductor wafer 1 is diced along dicing lines 3 to cut off into each semiconductor chip 2. Here, the semiconductor chip 2 cut off is formed as an upper portion of the CoC structure and is called for an upper chip hereinafter. On the other hand, a semiconductor chip formed in a lower portion, which is called as a lower chip hereinafter, is not diced to be retained as a wafer state.

Here, a semiconductor production equipment 10 includes a plurality of compressing heads as shown in FIG. 2. In this embodiment, two compressing head, a first head 11 and a second head 12, are included in the semiconductor production equipment 10.

A semiconductor wafer 14 is disposed on a wafer stage 13 of the semiconductor production equipment 10, so that bump electrodes 15 of the lower chip 17 is set to be upturned. Here, the lower chip 17 having the CoC structure is formed in the semiconductor wafer 14. Further, the upper chip 2 being individualized is absorbed on the first head 11 of the semiconductor production equipment 10. Bump electrodes 16 of the upper chip 2 are set to be faced towards to the wafer stage 13. Furthermore, the bump electrodes 16 of the upper chip 2 absorbed on the first head 11 and the bump electrode 15 of the lower chip 17 absorbed on the semiconductor wafer 14 are aligned with each other. In an aligning process, first head 11 may be moved or the wafer stage 13 may be moved. Further, both the first head 11 and the wafer stage 13 may be moved.

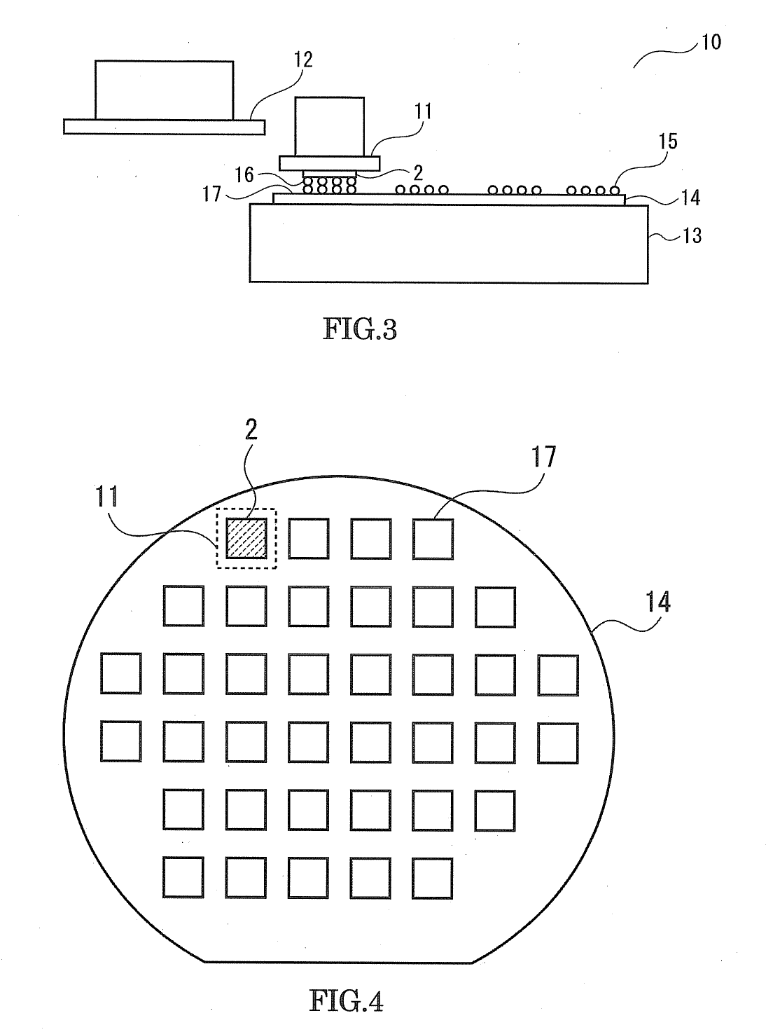

As shown in FIG. 3, the first head 11 is pushed down to press between the bump electrodes 16 of the upper chip 2 and the bump electrodes 15 of the lower chip 17, so that the bump electrodes 16 and the bump electrodes 15 are tentatively compressed each other, which is called for a tentative compression hereinafter.

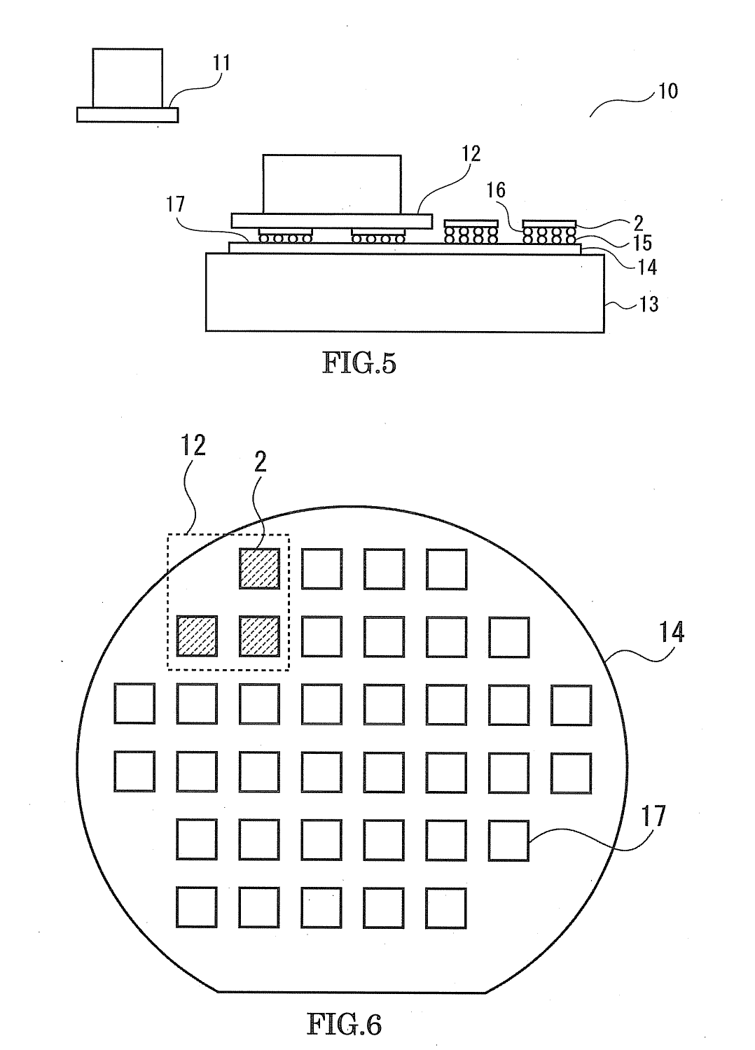

FIG. 4 is a top view of the semiconductor wafer 14 including the lower chip 17. The semiconductor chips 17 without lines show the lower chip before the tentative compression, and the semiconductor chips 2 with diagonal dot-lines show a state that the upper chip is tentatively compressed to the lower chip. FIG. 6 shows the same state as FIG. 5. In this figure, the chip is simply described as compressed or not. Accordingly, the upper chip 2 has the same size as the lower chip 17. However, the size of the lower chip specifically may have larger size than that of the upper chip.

As shown in FIG. 4, the upper chip 2 and the lower chip 17 on the semiconductor wafer 14 are tentatively compressed each other chip-by-chip. Here, the bump electrodes are not necessary to be strongly compressed, but is compressed not to move the upper chip 2 as degree of adhesion. Consequently, the tentative compression is performed at a temperature of 250° C. and a pressure of 1 mN/bump for one second as a compressing condition, for example. In such a manner, the compression is ended for a short period. In the tentative compression process, a material in Sn series, for example, Sn, Sn—Ag, Sn—Cu, Sn—Ag—Cu, Sn—Au, Sn—In, Sn—Sm or the like is preliminarily adhered on the bump electrode, subsequently, the first head 11 or the wafer stage 13 is heated to compress the material of the Sn series in the tentative compression process. Furthermore, the tentative compression process may be performed with ultrasonic to remove an oxide film formed on the bump electrode.

As shown in FIG. 5, the upper chip 2 and the lower chip 17 of the semiconductor wafer 14 which are tentatively compressed are strongly compressed, which is called for a fixed compression hereinafter. In the fixed compression process, the second head 12 is set on the upper chip 2 to press the upper chip 2 tentatively compressed. As a head area of the second head 12 is larger than the first head 11, as shown in FIG. 6, a plurality of the upper chips 2 can be set to be pressed by the first head 11 in one compression process. Namely, the second head 12 or the wafer stage 13 is heated, the material of the Sn series preliminarily adhered on the bump electrode can be pressed to simultaneously compress between the bump electrodes 16 of the plurality of the upper chips 2 and the bump electrodes of the lower chips 17 on the semiconductor wafer 14.

The upper chip and the lower chip can be precisely compressed, for example, at a temperature of 280° C., pressure of 1 mN/bump, for 15 seconds. The fixed compression process has a longer takt time as compared to that of the tentative compression process. On the other hand, as a unit with a plural semiconductor chips can be simultaneously compressed to the semiconductor wafer, the takt time of the compression process can be shortened as compared to the compression process with chip-by-chip.

As the fixed compression can precisely compress between the upper chip and the lower chip, a temperature condition and a pressure condition may desirably be set as the same as or higher than those of the tentative compression process.

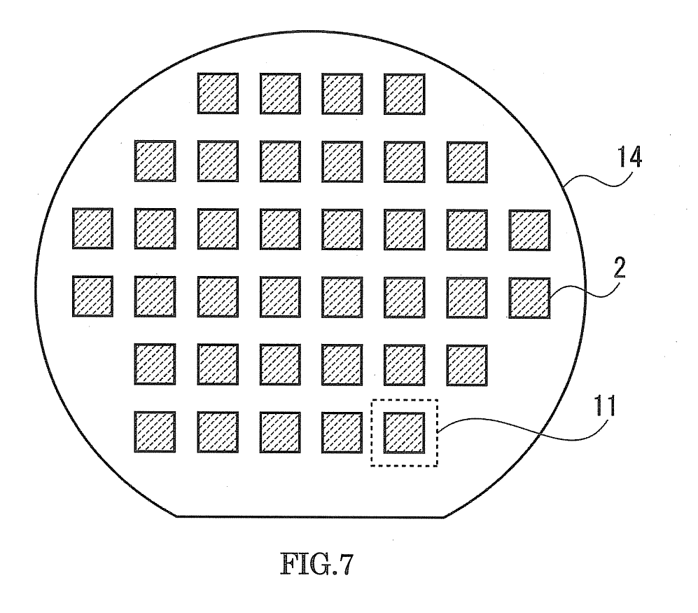

FIGS. 7-13 are plane views showing the semiconductor wafer 14. As same as shown in FIG. 4 mentioned above, the semiconductor chip 14 without lines shows the lower chip before the upper chip is tentatively compressed. In other words, the lower chip 17 is exposed. The semiconductor chip with dotted diagonal-lines shows the upper chip which is tentatively compressed on the lower chip, and the semiconductor chip with solid diagonal-lines shows the upper chip is fixedly compressed on the lower chip. Namely, the upper chip 2 is exposed in the semiconductor chip with the dotted diagonal lines or the solid diagonal lines.

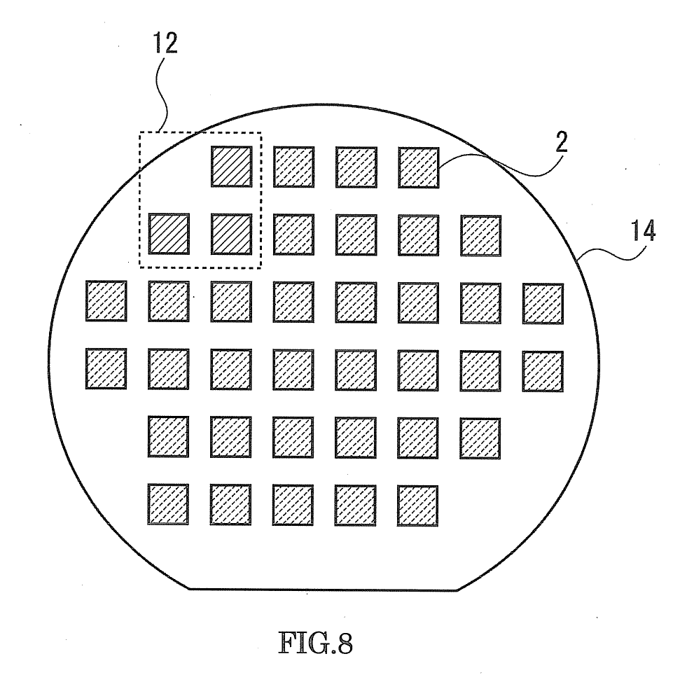

The fixed compression is performed after the tentative compression is ended. However, all the upper chips 2 are tentatively compressed as shown in FIG. 7, subsequently, a plurality of the upper chips 2 are fixedly compressed on the lower chips 17 as shown in FIG. 8.

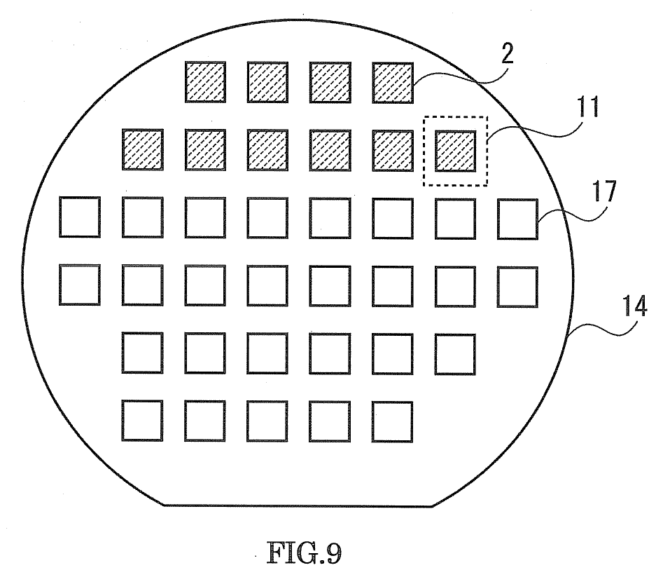

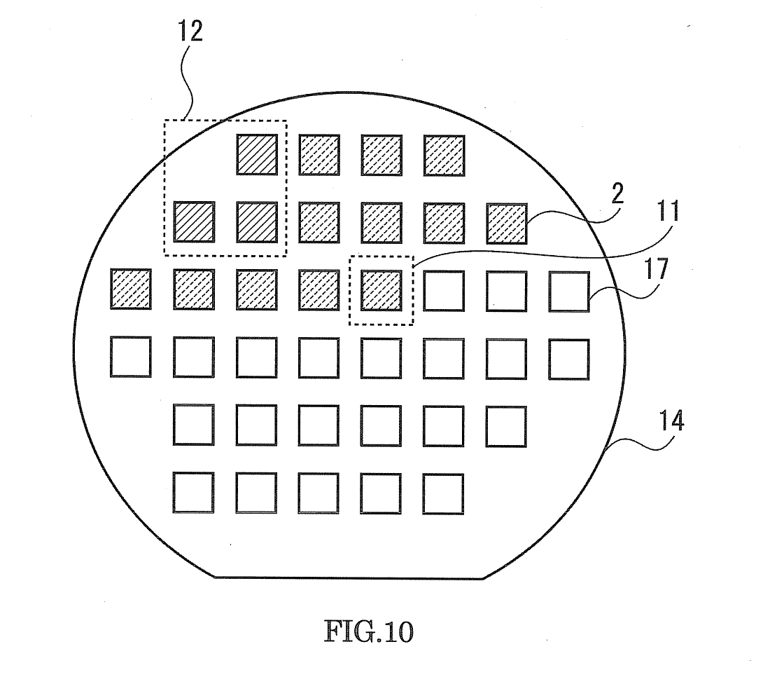

As shown in FIGS. 9 and 10 the fixed compression may be performed with the tentative compression as a processing step. The tentative compression is performed by two lows as shown in FIG. 9, subsequently, the fixed compression is performed in two lows by two columns with the tentative compression as shown in FIG. 10. In such a way, the tentatively compression and the fixed compression can be parallel performed to shorten a takt time of the processing steps.

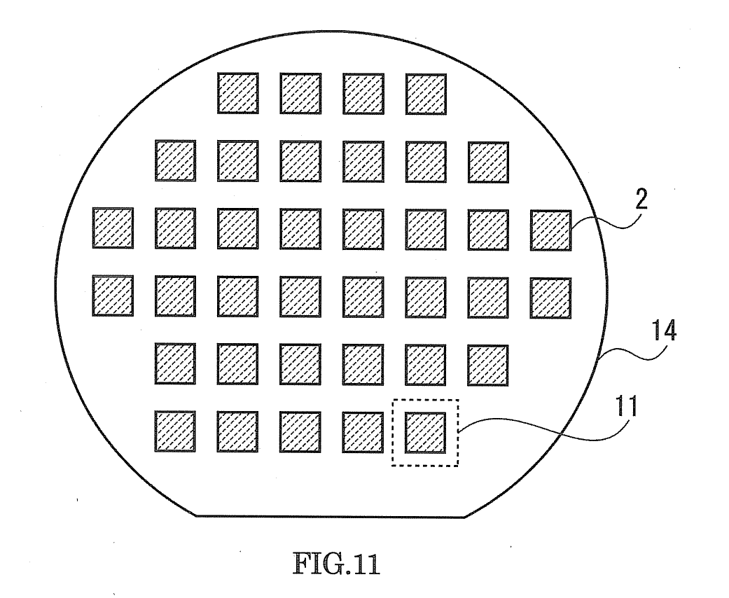

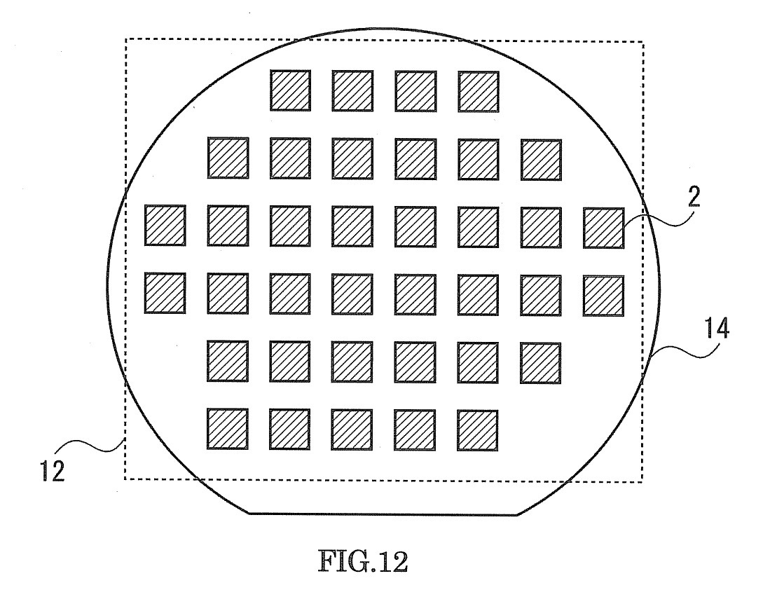

The lower chips 17 on the semiconductor wafer 14 and all of the upper chips 2 can be tentatively compressed as shown in FIG. 11, subsequently, each upper chip 2 and each lower chip 17 can be fixedly compressed as shown in FIG. 12 by using the second head 12 having a surface area which is the same as or larger than that of the semiconductor wafer

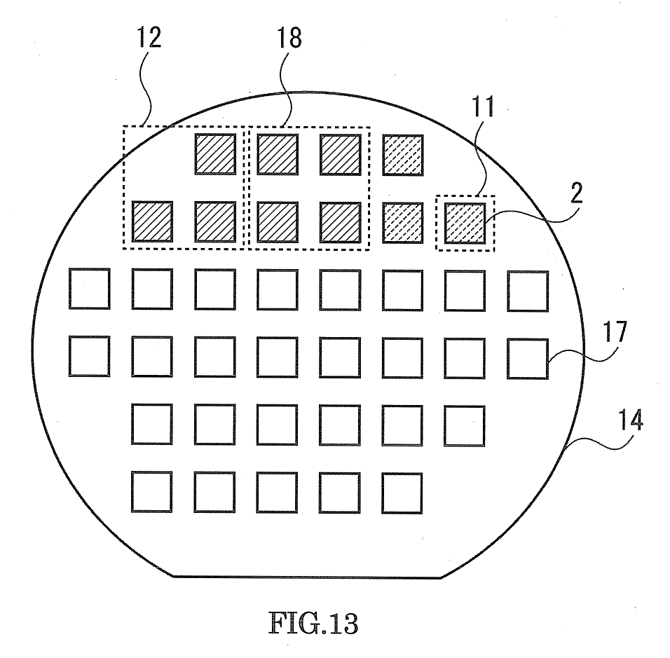

Furthermore, a number of the compressing heads is not restricted one first head 11 and one second head 12. Namely, compressing heads more than three can provide an advantage of the present disclosure, for example, as shown in FIG. 13, the semiconductor chip can be tentatively compressed by one first head 11, another semiconductor chips can be fixedly compressed in parallel by other two second heads 12, 18. Of course, a plurality of the first heads 11 may be available. The takt time in the compression process of semiconductor chip can be further shortened.

As mentioned above, the fixed compression is performed as a unit of four semiconductor chips with two lows by two columns. However, the fixed compression is not restricted the above case. a plurality of the semiconductor chips may be available. The takt time of the compression process on one semiconductor wafer is decreased with increasing semiconductor chips by one compression.

After the semiconductor chip is connected to the CoC structure, as mentioned above, an underfill resin is encapsulated in the semiconductor chip (not shown). The encapsulation of the underfill resin is performed to each semiconductor chip connected to the CoC structure. The encapsulation is performed after the fixed compression. However, the underfill resin can be parallel encapsulated with the fixed compression. Accordingly, it is not necessary to wait the encapsulation of the underfill resin till all of the semiconductor chips are fixedly compressed. As a result, the takt time can be decreased.

### Second Embodiment

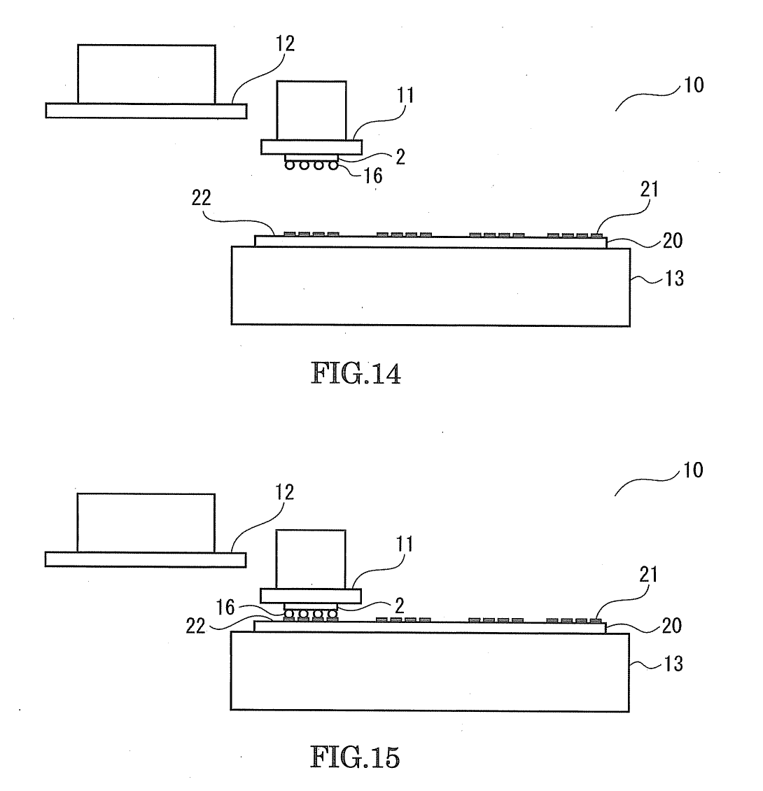

A method of fabricating a semiconductor device according to a second embodiment is shown in FIGS. 14-16 which are cross-sectional views, each showing a portion of a semiconductor production equipment.

In the first embodiment mentioned above, the bump electrode of the semiconductor chip being individualized and the bump electrode of the semiconductor chip formed in the semiconductor wafer are connected each other. This embodiment explains that one is a bump electrode and the other is a pad electrode.

Upper chips are individualized into each chip by using a dicing process as the same as the first embodiment. On the other hand, lower chips are retained as a wafer state. Here, an electrode of the upper chip is a bump electrode and an electrode of the lower chip is a pad electrode.

As shown in FIG. 14, the semiconductor wafer 20 is disposed on a wafer stage 13 of the semiconductor production equipment 10, so that bump electrodes 15 of a lower chip 22 is set to be upturned. Here, nickel as a metal material, for example, may be preliminarily adhered on the pad electrode for compression with the bump electrode. Further, the upper chip 2 is absorbed on the first head 11 of the semiconductor production equipment 10. Bump electrodes 16 of the upper chip 2 is set to be faced towards to the wafer stage 13. Furthermore, the bump electrodes 16 of the upper chip 2 absorbed on the first head 11 and the bump electrode 21 of the lower chip 22 absorbed on the semiconductor wafer 20 are aligned with each other. In an aligning process, first head 11 may be moved or the wafer stage 13 may be moved. Further, both the first head 11 and the wafer stage 13 may be moved.

As shown in FIG. 15, the first head 11 is pushed down. The bump electrodes 16 of the upper chip 2 and the pad electrodes 21 of the lower chip 22 are tentatively compressed each other as the same as the first embodiment. Here, the bump electrode 16 and the pad electrode 21 are not necessary to be strongly compressed each other, but is compressed not to move the upper chip 2 as degree of adhesion. Consequently, the tentative compression is performed at a temperature of 250° C. and a pressure of 1 mN/bump for one second as a compressing condition, for example. In such a manner, the tentative compression is ended for a short takt time. In the tentative compression, a material in a Sn series, for example, Sn, Sn—Ag, Sn—Cu, Sn—Ag—Cu, Sn—Au, Sn—In, Sn—Sm or the like is preliminarily adhered on the bump electrode, subsequently, the first head 11 or the wafer stage 13 is heated to compress the material of the Sn series in the tentative compression. Furthermore, the tentative compression may be performed with ultrasonic to remove an oxide film formed on the bump electrode.

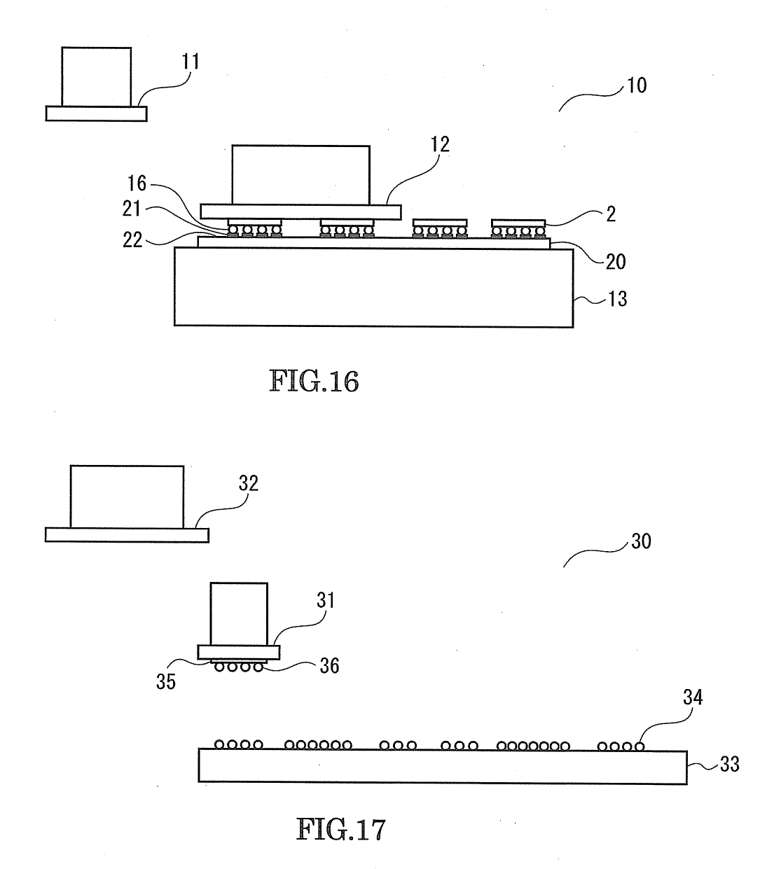

As shown in FIG. 16, the upper chip 2 and the lower chip 22 of the semiconductor wafer 20 which are tentatively compressed are strongly compressed. As the head area of the second head 12 is larger than that of the first head 11, as described in the first embodiment, a plurality of the upper chip 2 can be set to be pressed on the under chips 22 on the semiconductor wafer 20 by the first head 11 in one compressing process. Namely, the second head 12 or the wafer stage 13 is heated, the material of the Sn series preliminarily adhered on the bump electrode can be pressed to simultaneously compress between the bump electrodes 16 of the plurality of the upper chip 2 and the pad electrodes 21 of the lower chip 22 on the semiconductor wafer 20.

The upper chip and the lower chip can be precisely compressed, for example, at a temperature of 280° C., pressure of 1 mN/bump, for 15 seconds. The fixed compression has a longer takt time as compared to that of the tentative compression. On the other hand, as a unit with a plural semiconductor chips can be simultaneously compressed to the semiconductor wafer, the takt time of the compression process can be shortened as compared to the compressing process with chip-by-chip.

As the fixed compression can precisely compress between the upper chip and the lower chip, a temperature condition and a pressure condition may be set as the same as or higher than those of the tentative compression.

Furthermore, the same effects may be provided in a case that the electrode of the upper chip 2 is a pad electrode and the electrode of the lower chip 17 is a bump electrode.

As the same as the first embodiment, after the semiconductor chip is connected to the CoC structure, as mentioned above, an underfill resin is encapsulated in the semiconductor chip (not shown). The encapsulation of the underfill resin is performed to each semiconductor chip connected to the CoC structure. The encapsulation is performed after the fixed compression. However, the underfill resin can be parallel encapsulated with the fixed compression. Accordingly, it is not necessary to wait the encapsulation of the underfill resin till all of the semiconductor chips are fixedly compressed. As a result, the takt time can be decreased.

### Third Embodiment

A method of fabricating a semiconductor device according to a third embodiment is shown in FIGS. 17-19 which are cross-sectional views, each showing a portion of a circuit substrate production equipment.

In the first embodiment and the second embodiment mentioned above, the semiconductor chip being individualized and the semiconductor chip formed on the semiconductor wafer are connected each other. This embodiment explains that one is a circuit substrate and the other is a semiconductor chip.

First, a semiconductor chip having a bump electrode is individualized by a dicing process as the same as the first embodiment and the second embodiment.

An electrode of a circuit substrate may be a bump electrode or a pad electrode. However, the electrode of the circuit substrate is a bump electrode in a case of the electrode of the semiconductor chip being the pad electrode. In other words, at least one of the electrodes being a bump electrode can provide as the third embodiment. Here, the third embodiment explains a case in which both the electrodes of the circuit substrate and the semiconductor chip are bump electrodes.

As shown in FIG. 17, a circuit substrate 33 is fixedly disposed on a wafer stage (not illustrated). A surface of the circuit substrate 33 disposed a semiconductor chip 35 is set to be upturned. Further, the semiconductor chip 35 is absorbed on a first head 31 of a circuit substrate production equipment 30. Bump electrodes 36 of the semiconductor chip 35 is set to be faced with the circuit substrate 33. Furthermore, the bump electrodes 36 of the semiconductor chip 35 absorbed on the first head 31 and the bump electrodes 34 of the substrate 33 absorbed on the first head 30 are aligned with each other. In an aligning process, first head 31 may be moved or the substrate 33 may be moved. Further, both the first head 11 and the substrate 33 may be moved.

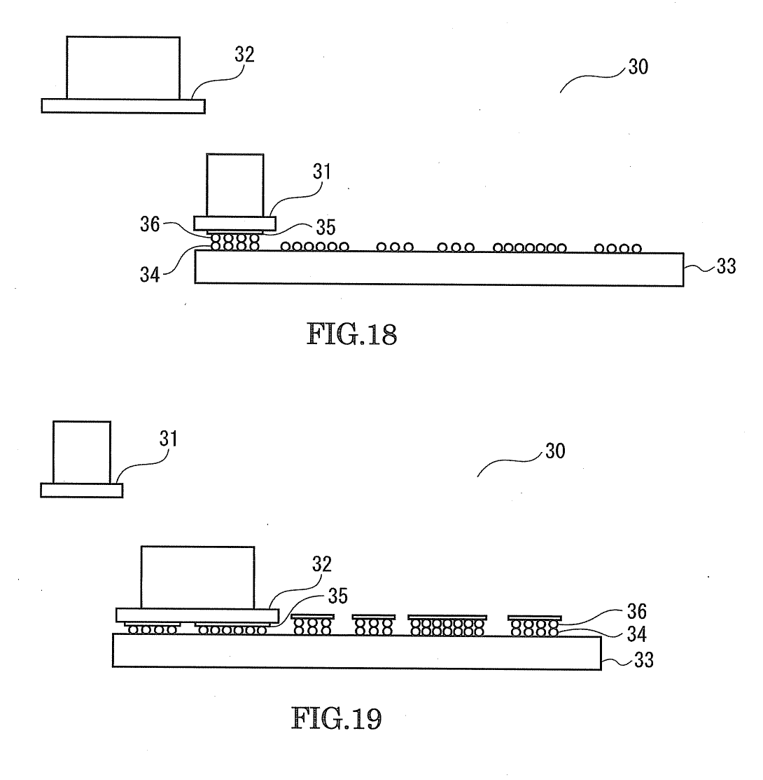

As shown in FIG. 18, the first head 31 is pushed down. The bump electrodes 36 of the semiconductor chip 35 and the bump electrodes 34 of the substrate 33 are tentatively compressed each other. Here, the bump electrode 34 and the bump electrode 36 are not necessary to be strongly compressed each other, but is compressed not to move the semiconductor chip 35 as degree of adhesion. Consequently, the tentative compression is performed at a temperature of 250° C. and a pressure of 1 mN/bump for one second as a compressing condition, for example. In such a manner, the tentative compression is ended for a short takt time, a few seconds as the same as the first embodiment and the second embodiment. In the tentative compression, a material in a Sn series, for example, Sn, Sn—Ag, Sn—Cu, Sn—Ag—Cu, Sn—Au, Sn—In, Sn—Sm or the like is preliminarily adhered on the bump electrode, subsequently, the first head 11 or the wafer stage 13 is heated to compress the material of the Sn series in the tentative compression. Furthermore, the compression may be performed with ultrasonic to remove an oxide film formed on the bump electrode.

As shown in FIG. 19, the semiconductor chip 35 and the substrate 33 which are tentatively compressed as shown in FIG. 18 are strongly compressed. As the head area of the second head 32 is larger than the first head 31, as described in the first embodiment, a plurality of the semiconductor chips 35 can be set to be pressed on the substrate 33 in one compressing process. In such a manner, as an unit with a plural semiconductor chips can be simultaneously compressed to the substrate, the takt time of the compression process can be shortened as compared to the compression process with chip-by-chip.

While certain embodiments have been described, these embodiments have been presented by way of example only, and are not intended to limit the scope of the inventions. Indeed, the novel methods and equipments described herein may be embodied in a variety of other forms; furthermore, various omissions, substitutions and changes in the form of the methods and equipments described herein may be made without departing from the spirit of the inventions. The accompanying claims and their equivalent are intended to cover such forms or modifications as would fall within the scope, and sprit of the inventions.

What is claimed is:

1. A method of fabricating a semiconductor device, comprising:
tentatively compressing a second electrode formed on a second semiconductor chip in a substrate to a first electrode on a first semiconductor chip, at least one of the first electrode and the second electrode being constituted with a metal protrusion; and
fixedly compressing the second electrode to the first electrode.

2. The method of claim 1, wherein
the substrate is a semiconductor substrate.

3. The method of claim 1, wherein
the substrate is a circuit substrate.

4. The method of claim 1, wherein
both the first electrode and the second electrode are constituted with the metal protrusion.

5. The method of claim 1, wherein
a material of the metal protrusion is constituted with Sn or Sn-compound.

6. The method of claim 5, wherein
the Sn-compound is constituted with at least one of Sn—Ag, Sn—Cu, Sn—Ag—Cu, Sn—Au, Sn—In, and Sn—Sm.

7. The method of claim 1, wherein
one of the first electrode and the second electrode is the metal protrusion, the other is a pad electrode.

8. The method of claim 1, wherein
a material of the pad electrode is constituted with Ni.

9. The method of claim 1, wherein
the second semiconductor chip is corresponded to the first semiconductor chip one-by-one in tentatively compressing, and each of the second semiconductor chips are simultaneously compressed with the first semiconductor chips in fixedly compressing.

10. The method of claim 1, wherein
the second the semiconductor chip is smaller than the first semiconductor chip.

11. The method of claim 1, wherein
the substrate is heated at a first temperature in tentatively compressing and is heated at a second temperature in fixedly compressing.

12. The method of claim 11, wherein
the second temperature is higher than the first temperature.

13. The method of claim 12, wherein
the second temperature is set to be 280° C. and the first temperature is set to be 250° C.

14. The method of claim 1, wherein
an oxide film on a surface of the first electrode is removed by ultrasonic in tentatively compressing.

15. The method of claim 1, wherein
tentatively compressing is performed concurrently with fixedly compressing.

16. An equipment of fabricating a semiconductor device, comprising:
a wafer stage; and
a plurality of compressing heads.

17. The equipment of claim 1, wherein
the plurality of compressing heads includes a first head and a second head, an area of the wafer stage corresponded to the second head is larger than an area of the wafer stage corresponded to the first head.

18. The equipment of claim 1, wherein
the first head is used in tentatively compressing and the second head is used in fixedly compressing.

19. The equipment of claim 1, wherein
the wafer stage includes a heating mechanism.

20. The equipment of claim 1, wherein
the wafer stage includes a ultrasonic mechanism.
